(19) United States
(12) Patent Application Publication
(10) Pub. No.: US 2026/0173884 A1
(43) Pub. Date: Jun. 18, 2026

(54) SEMICONDUCTOR PACKAGING STRUCTURE AND MANUFACTURING METHOD THEREOF

(71) Applicant: Taiwan Semiconductor Manufacturing Company, Ltd., Hsinchu (TW)

(72) Inventors: Cheng-Yu HSIEH, Hsinchu (TW); Yang-Che CHEN, Hsinchu (TW); Wei-Yu CHOU, Hsinchu (TW); Hsiang-Tai LU, Hsinchu (TW); Wei-Ray LIN, Hsinchu (TW)

(73) Assignee: Taiwan Semiconductor Manufacturing Company, Ltd., Hsinchu (TW)

(21) Appl. No.: 18/980,048

(22) Filed: Dec. 13, 2024

(51) Int. Cl. H01L 23/552; H01L 21/50; H01L 23/31; H01L 23/498

(52) U.S. Cl. CPC H10W 42/20; H10W 70/65; H10W 74/111; H10W 95/00

(57) ABSTRACT

A semiconductor packaging structure includes a redistribution structure, a semiconductor device, a filling layer and a shielding structure. The redistribution structure includes at least one conductive layer, the semiconductor device is disposed on one side of the redistribution structure and is electrically connected to the conductive layer. The filling layer covers the periphery of the semiconductor device and has an accommodating portion. The shielding structure is disposed in the filling layer. The shielding structure includes a soldering material, and the soldering material is suitable for filling the accommodating portion to cover the semiconductor device.

### BACKGROUND

Semiconductor devices and integrated circuits (ICs) are used in a variety of electronic applications, such as personal computers, cell phones, digital cameras, and other electronic equipment. For example, the semiconductor devices and ICs are typically manufactured on a single semiconductor wafer. The dies of the wafer may be processed and packaged with other semiconductor devices, dies or components at the wafer level or after wafer-sawing, and various technologies have been developed. Semiconductor processing for fabrications of the semiconductor devices and ICs continues to evolve towards increasing device-density, higher numbers of active devices (mainly transistors) of ever decreasing device dimensions. As electronic products are continuously miniaturized, the electromagnetic interference (EMI) shielding of the packaged semiconductor devices and ICs has become important for packaging technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a semiconductor packaging structure according to an embodiment of the present disclosure.

FIG. 1B is a top view of the semiconductor packaging structure of FIG. 1A.

FIG. 1C is a schematic diagram of the semiconductor packaging structure in FIG. 1A disposed on a substrate.

FIG. 2 is a schematic cross-sectional view of a semiconductor packaging structure according to an embodiment of the disclosure.

FIG. 3 is a schematic cross-sectional view of a semiconductor packaging structure according to another embodiment of the present disclosure.

FIGS. 4A to 4D are schematic diagrams of a method for manufacturing a semiconductor packaging structure according to an embodiment of the present disclosure.

FIGS. 5A to 5D respectively illustrate cross-sectional schematic diagrams corresponding to various steps of the method for manufacturing the semiconductor packaging structure of FIGS. 4A to 4D.

FIG. 5E illustrates a schematic cross-sectional view of a semiconductor packaging structure according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

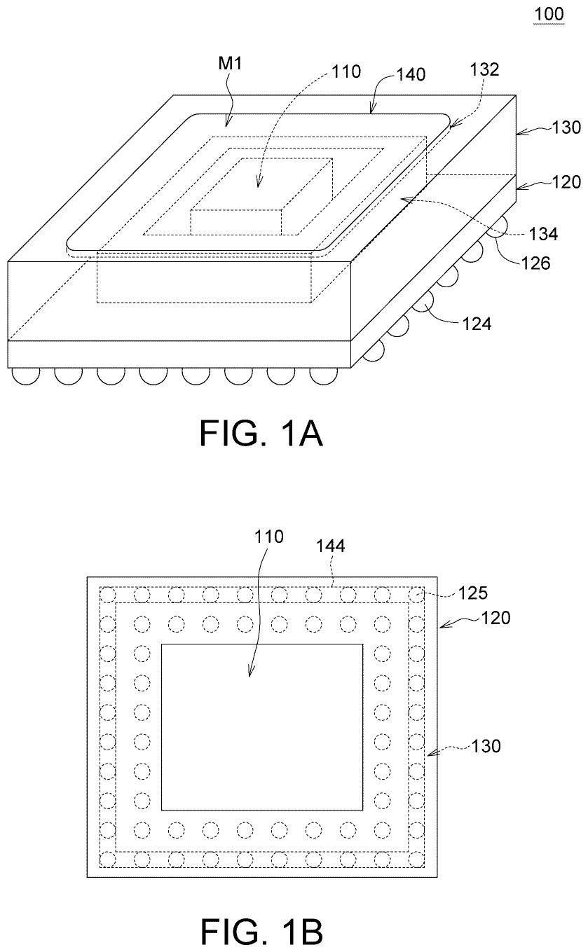

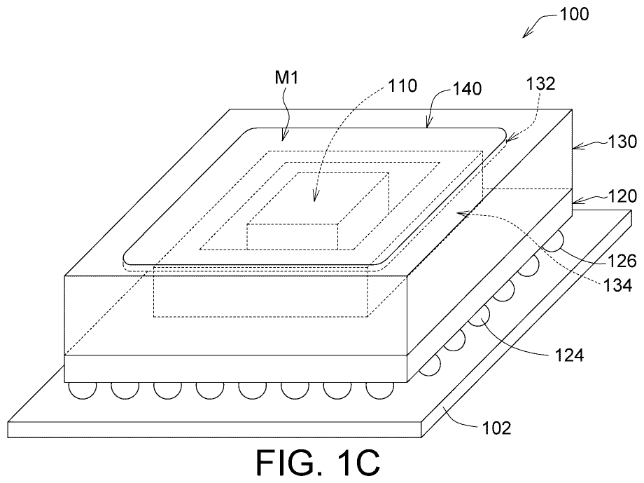

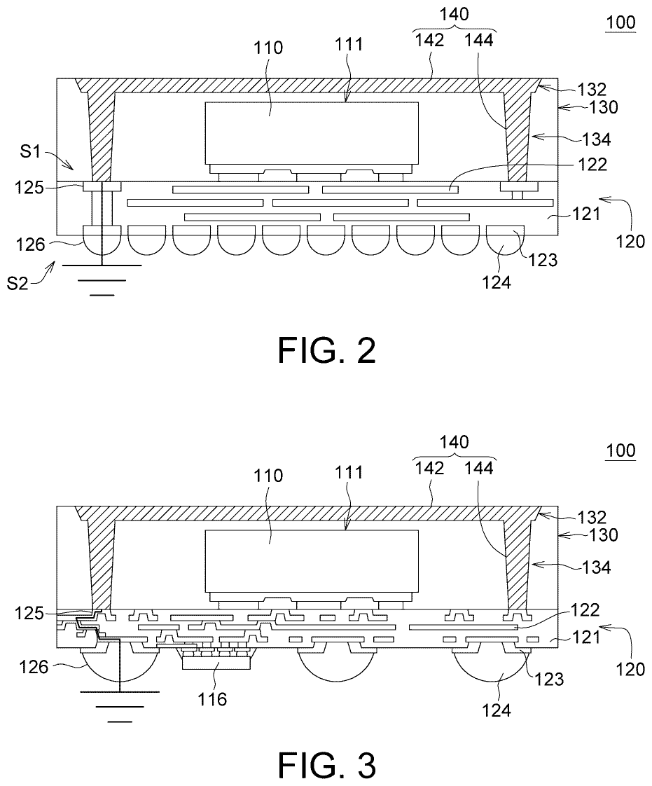

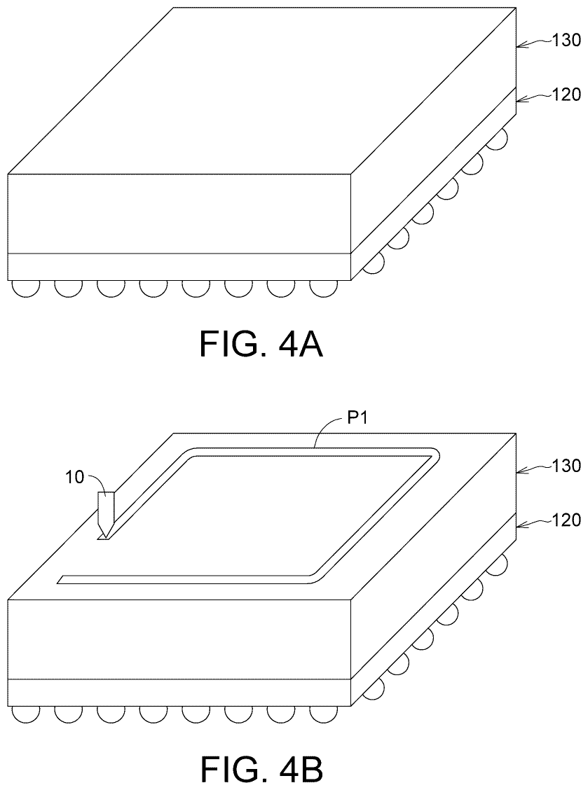

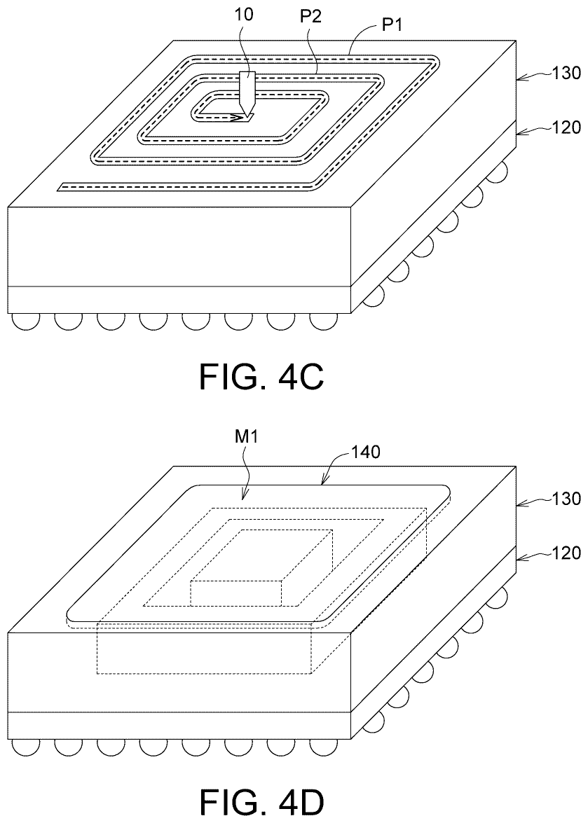

Referring to FIGS. 1A to 3, FIG. 1A is a schematic diagram of a semiconductor packaging structure 100 according to an embodiment of the present disclosure, FIG. 1B is a top view of the semiconductor packaging structure 100 of FIG. 1A, and FIG. 1C is a schematic diagram of the semiconductor packaging structure 100 in FIG. 1A disposed on a substrate 102. FIG. 2 is a schematic cross-sectional view of a semiconductor packaging structure 100 according to an embodiment of the present disclosure. FIG. 3 is a schematic cross-sectional view of a semiconductor packaging structure 100 according to another embodiment of the present disclosure.

The semiconductor packaging structure 100 includes a semiconductor device 110, a redistribution structure 120, a filling layer 130 and a shielding structure 140. The redistribution structure 120 includes at least a conductive layer 122, a ground pad 125 and a conductive bump 126. The ground pad 125 is disposed on a first side S1 of the redistribution structure 120, the conductive bump 126 is disposed on a second side S2 of the redistribution structure 120, and the first side S1 is opposite to the second side S2. The filling layer 130 covers a periphery of the semiconductor device 110 and has an upper cover accommodating portion 132 and an outer ring accommodating portion 134. The upper cover accommodating portion 132 is located above the semiconductor device 110. The outer ring accommodating portion 134 is located around the semiconductor device 110. The shielding structure 140 contains a soldering material M1, and the soldering material M1 is suitable for filling the upper cover accommodating portion 132 and the outer ring accommodating portion 134 to cover the semiconductor device 110. In one embodiment, the soldering material M1 is, for example, solder paste or lead-free solder, such as Sn—Pb alloy, Sn—0.7Cu alloy or Sn—Ag—Cu alloy.

In FIG. 1B, the ground pad 125 is connected to the outer ring sidewall 144 of the shielding structure 140 to form a EMI shielding structure around the semiconductor device 110. In addition, in FIGS. 1B and 1C, the semiconductor packaging structure 100 is disposed on the substrate 102 via the conductive bump 126 and the solder balls 124, and the shielding structure 140 are electrically connected to the substrate 102 via the ground pad 125 and the conductive bump 126 form a ground structure, so that the static electricity or current passing through the shielding structure 140 can be led to the ground of the substrate 102 via the ground pad 125 and the conductive bump 126. In one embodiment, the substrate 102 can be a printed circuit board.

According to some embodiments, although only a single semiconductor device 110 (such as a system-on-chip (SoC)) is shown in the figure, in another embodiment, a plurality of semiconductor devices 110 may be are incorporated into the same packaging structure 100 and electrically connected to each other. In addition, in FIG. 3, the independent passive device (IPD) 116 can be integrated into the same packaging structure 100 to form a three-dimensional system integrated chip (SoIC) packaging structure.

The system on integrated chips (SoIC) packaging technology adopted by the semiconductor device 110 of the present embodiment is based on wafer-on-wafer (WoW) and chip-on-wafer (CoW) multi-chip stacking technologies, the dies are stacked in a face-to-face or face-to-back manner, and through silicon via (TSV) technology and micro-bumps are used to connect multiple semiconductor dies to each other. The semiconductor device 110 may be a central processing unit (CPU) die, a graphics processing unit (GPU) die, a system-on-a-chip (SoC) unit die or a high bandwidth memory (HBM), a power management die (for example, power management integrated circuit (PMIC), a radio frequency (RF) die, a sensor die, a micro-electro-mechanical-system (MEMS) die, a signal processing die (such as digital signal processor, DSP) etc., and the present disclosure is not limited thereto.

The semiconductor packaging structure 100 of present embodiment can be achieved using fan-out wafer level packaging (FOWLP) technology. FOWLP is an improvement on wafer level packaging (WLP) and can provide more external connections for the semiconductor device 110 (such as a silicon chip). The semiconductor device 110 is embedded in an epoxy molding material (EMC), and then a high-density redistribution structure 120 (RDL) is constructed on the active surface of the semiconductor device 110 and copper bumps or solder bumps are used as die bonding structures to form a reconstituted wafer.

The redistribution structure 120 is located on one side of the filling layer 130. The redistribution structure 120 may include a plurality of redistribution dielectric layers 121, a plurality of redistribution wiring interconnects (i.e., conductive layers 122) and a plurality of bonding pads 123. Each of the redistribution dielectric layers 121 includes a dielectric polymer material, such as polyimide (PI), benzocyclobutene (BCB) or polybenzobisoxazole (PBO). Each of the redistribution dielectric layers 121 may be formed by spin coating and drying the dielectric polymer material. The thickness of each redistribution dielectric layer 121 may be in the range of 2 microns to 40 microns (e.g., 4 microns to 20 microns). The photoresist layer can be applied over each redistribution dielectric layer 121 and patterned using an etching process (e.g., anisotropic etching process) to transfer the pattern in the photoresist layer into the redistribution dielectric layer 121. Subsequently, the photoresist layer can be removed by ashing, for example. Additionally, the metal fill material for the redistribution wiring interconnects 122 may include copper, nickel, or both copper and nickel. The thickness of the metal fill material deposited to form each of the redistribution wiring interconnects 122 may be in the range of 2 microns to 40 microns (e.g., 4 microns to 10 microns), but smaller or greater thicknesses may also be used. The total number of wiring levels in the redistribution structure 120 may range from 1 to 10.

The bonding pads 123 may have a rectangular, rounded rectangular or circular horizontal cross-sectional shape, and the thickness of the first bonding pads 123 may be in the range of 5 microns to 50 microns. In addition, the solder balls 124 can be formed on the first bonding pads 123, and the semiconductor packaging structure 100 and a carrier (e.g., a silicon substrate or a glass epoxy-based circuit board, etc.) are electrically connected to each other through the solder balls 124. In addition, the solder balls 124 may be ball grid array (BGA) connectors, metal pillars, controlled collapse chip connections (C4) bumps, bumps formed by electroless nickel-electroless palladium-immersion gold (ENEPIG) technology, or the like.

The filling layer 130 covers the semiconductor device 114. The filling layer 130 includes, for example, an epoxy molding compound (EMC). The EMC includes a compound containing epoxy resin, and the epoxy-containing compound can be hardened (i.e., cured) to provide the function of a dielectric material with sufficient hardness and mechanical strength. EMC may include epoxy resins, curing agents, silica (as filler material) and other additives. EMC can be available in liquid form or solid form depending on viscosity and fluidity. Liquid EMC generally provides better handling, good fluidity, fewer voids, better filling and fewer flow marks. Solid EMC generally provides less cure shrinkage, better stand-off, and less die drift. High filler content in EMC (e.g., 85% by weight) reduces molding time, molding shrinkage, and molding warpage. Uniform filler size distribution in EMC can reduce flow marks and enhances flow. The curing temperature of EMC can be lower than the release (peel) temperature of the die attach film (DAF).

Additionally, an underfill material (not shown) is formed around each joined array of solder balls 124, such as by injecting underfill around the array of solder balls 124 after reflowing the solder balls 124, to protect the IPD 116 and the solder balls 124.

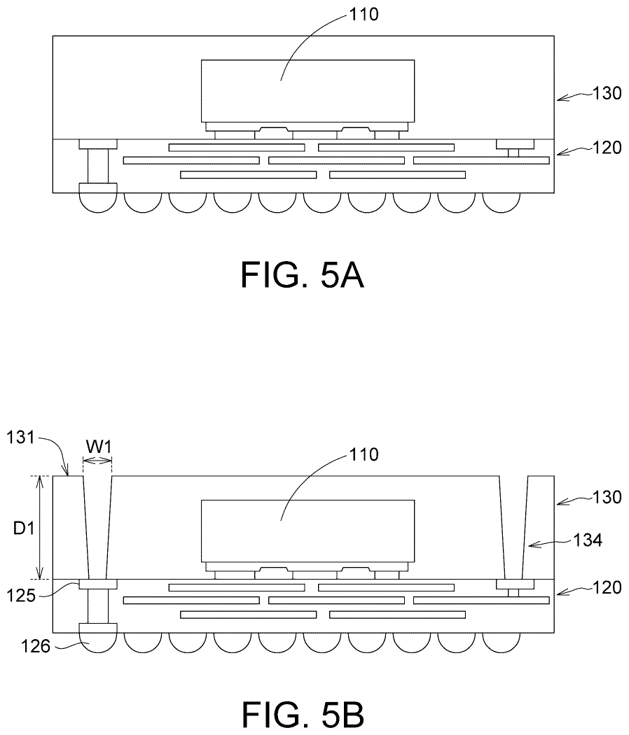

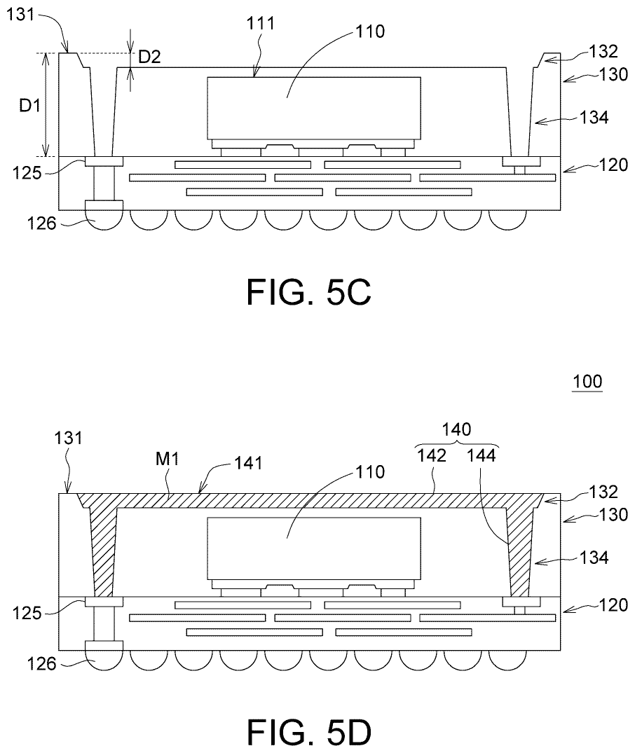

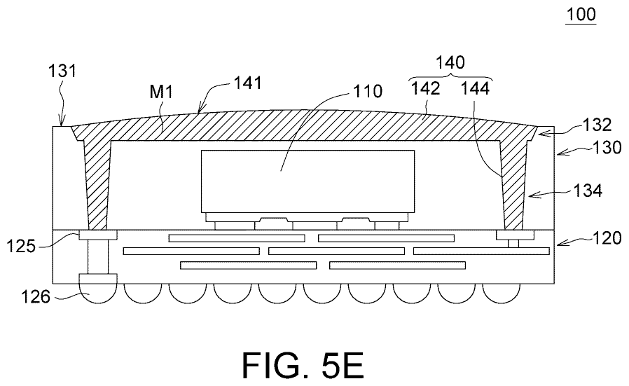

The following describes a method for manufacturing the semiconductor packaging structure 100. Please refer to FIGS. 4A to 4D, schematic diagrams of a method for manufacturing the semiconductor packaging structure 100 according to an embodiment of the present disclosure are illustrated. FIGS. 5A to 5D are respectively schematic cross-sectional views corresponding to various steps of the method for manufacturing the semiconductor packaging structure 100 of FIGS. 4A to 4D, in which the cross-sectional view of FIG. 5A corresponds to the step of FIG. 4A, the cross-sectional view of FIG. 5B corresponds to the step of FIG. 4B, the cross-sectional view in FIG. 5C corresponds to the step of FIG. 4C, and the cross-sectional view in FIG. 5D corresponds to the step in FIG. 4D.

Referring to FIG. 4A and FIG. 5A, a semiconductor device 110 is disposed on a redistribution structure 120. The semiconductor device 110 is disposed on one side of the redistribution structure 120 and is electrically connected to a conductive layer 122 of the redistribution structure 120. In addition, a filling layer 130 is formed to cover the semiconductor device 110, and the filling layer 130 is cured to embed the semiconductor device 110 into the filling layer 130. The filling layer 130 includes, for example, an epoxy molding compound (EMC) or other thermally curable material. The height of the filling layer 130 is greater than the height of the semiconductor device 110 so that the top surface 111 of the semiconductor device 110 and the top surface 131 of the filling layer 130 are not coplanar and are separated from each other by a predetermined distance.

Referring to FIG. 4B and FIG. 5B, laser 10 is used to locally heat the filling layer 130. After the filling material absorbs the energy of the laser 10, the heat energy can help the solvent to volatilize and cause a portion of the filling layer 130 to be ablated, which is called laser drilling process. Since the temperature of the filling material after absorbing the energy of the laser 10 may be higher than 200 degrees, for example, 250 degrees, a part of the filling material is removed, and the remaining filling material remains in an original cured state. As shown in FIG. 5B, the laser 10 is used to ablate a first portion of the filling layer 130. The first portion includes an outer ring accommodating portion 134 penetrating the filling layer 130. The outer ring accommodating portion 134 is located corresponding to the periphery of the semiconductor device 110 and can be a circular or square structure. In one embodiment, the recess depth D1 (the distance extending from the top surface 131 to the lower surface of the filling layer 130) of the outer ring accommodating portion 134 of the filling layer 130 can be achieved by adjusting the power of the laser 10. In addition, the lateral aperture or thickness W1 of the outer ring accommodating portion 134 can be controlled by beam size of laser 10, which is able to adjust the shielding dimension to meet the electrical performance requirement. After the laser 10 ablates the first portion of the filling layer 130, at least one ground pad 125 can be exposed at the bottom of the outer ring accommodating portion 134. The ground pad 125 is disposed on a first side S1 of the redistribution structure 120, and the ground pad 125 and the conductive bump 126 disposed on a second side S2 of the redistribution structure 120 are electrically connected through the conductive vias to form a grounded structure. The conductive bump 126 may be solder ball, ball grid array (BGA) connectors, metal pillars, controlled collapse chip connections (C4) bumps, bumps formed by electroless nickel-electroless palladium-immersion gold (ENEPIG) technology, or the like.

Referring to FIG. 4C and FIG. 5C, the laser 10 is used to continue to ablate the filling layer 130 to remove a second portion of the filling layer 130. The second portion includes an upper cover accommodating portion 132 connected to the outer ring accommodating portion 134. The upper cover accommodating portion 132 is located correspondingly above the semiconductor device 110. In addition, the depth D2 of the upper cover accommodating portion 132 is smaller than the depth D1 of the outer ring accommodating portion 134. The recess depth D2 of the upper cover accommodating portion 132 on the filling layer 130 can be achieved by adjusting the power of the laser 10. In some embodiments, the upper cover accommodating portion 132 may expose the top surface 111 of the semiconductor device 110 (not shown), or the upper cover accommodating portion 132 may not expose the top surface 111 of the semiconductor device 110 (see FIG. 5C, there is still filling material between the upper cover accommodating portion 132 and the top surface 111 of the semiconductor device 110 to maintain an appropriate distance).

In some embodiments, laser ablation uses high photon energy (i.e., short wavelength, and not necessarily high intensity) to remove the encapsulating material of filling layer 130 and is an effective method for patterning polymers. Typically, ultraviolet (UV) light is radiated on the polymer at moderate intensity, allowing a combination of photochemical and photothermal effects to dissociate the polymer chains into smaller volatile molecules. For example, laser ablation has been successfully used to pattern materials with a resolution limit of less than 5 μm. Laser ablation rate is a function of wavelength, pulse width and energy density, so the ablation rate can be precisely controlled. Laser ablation can be successfully demonstrated using an excimer laser. Excimer lasers are the powerful UV laser sources and usually contain rare gases and halogens or halogen-containing gases. Commonly used excimer laser gases are KrF (248 nm) and ArF (193 nm). Unlike other lasers, excimer lasers produce spotless and non-interfering light, which is ideal for high-resolution lithography. Excimer lasers are ideally suited for laser ablation because they efficiently emit light in the UV spectrum, have large beams, and can be easily used to form arbitrary patterns (such as vias or trenches). In some embodiments, an ultraviolet (UV) excimer laser at 193 nm, 248 nm, 308 nm, or 355 nm wavelength may be used, such as to illuminate the filling layer 130 during laser ablation period of a mask scan or spot illumination to form the required pattern (i.e., the upper cover accommodating portion 132 and the outer ring accommodating portion 134).

In some embodiments, the path of laser ablation can be distributed in a spiral shape from outside to inside (as shown in FIG. 4B and FIG. 4C), or an outer ring ablation path P1 (see FIG. 4B) can be first formed on the filling layer 130 to remove the first portion of the filling layer 130 and then a back-and-forth ablation path P2 (e.g., S-shaped) in the space surrounded by the outer ring ablation path P1 can be formed to remove the second portion of the filling layer 130.

Referring to FIG. 4D, FIG. 5D and FIG. 5E, a soldering material M1 is filled into the upper cover accommodating portion 132 and the outer ring accommodating portion 134 to form a shielding structure 140. The soldering material M1 can be formed in the filling layer 130 by printing or coating, so that the soldering material M1 can fill the upper cover accommodating portion 132 and the outer ring accommodating portion 134. The top surface 141 of the shielding structure 140 is substantially coplanar with or slightly protrudes from the top surface 131 of the filling layer 130 (shown in FIG. 5E). In some embodiments, since the shielding structure 140 is disposed in the filling layer 130, the shielding structure 140 does not occupy the space outside the filling layer 130, and the shielding structure 140 does not need to cover the sidewall of the filling layer 130, nor does it need to made the metal layer extending downward along the sidewall of the filling layer 130 to be electrically connected to the redistribution structure 120, thereby reducing the keep out zone (KOZ) on the bottom of the redistribution structure 120.

The soldering material M1 is, for example, solder paste or lead-free solder. When the heating temperature is higher than the melting point of the solder paste or lead-free solder, the soldering material M1 begins to melt and can be filled into the upper cover accommodating portion 132 and the outer ring accommodating portion 134. After the temperature is lower than the melting point of the solder paste or lead-free solder, the solder material M1 solidifies to serve as a shielding structure 140 to prevent electromagnetic interference (EMI).

In some embodiments, the shielding structure 140 includes an upper cover 142 and an outer ring sidewall 144. The upper cover 142 and the outer ring sidewall 144 are connected to form a closed housing covering the semiconductor device 110. The upper cover 142 is located above the semiconductor device 110, and the outer ring sidewall 144 is located around the semiconductor device 110. In addition, the shielding structure 140 can be electrically connected to the ground pad 125. As shown in FIG. 5D, the bottom of the outer ring sidewall 144 of the shielding structure 140 is electrically connected to the ground pad 125, and the ground pad 125 and the conductive bump 126 provided on the second side S2 of the redistribution structure 120 are electrically connected through conductive vias to form a ground structure. Therefore, the static electricity or current passing through the shielding structure 140 can be led to the ground via the ground pad 125 and the conductive bump 126 for potential neutralization (discharge). The conductive bump 126 can be one solder ball located at the corner of BGA connectors.

The present disclosure relates to a semiconductor packaging structure and a manufacturing method thereof, wherein an EMI shielding configuration is provided in the filling layer, that is, a built-in-molding solder ring and a molding solder cover are provided to have a shielding structure around the semiconductor device. The EMI shielding structure can be electrically connected to a ground pad and a conductive bump at the corner to form a ground structure.

According to some embodiments of the present disclosure, a semiconductor packaging structure includes a redistribution structure, a semiconductor device, a filling layer and a shielding structure. The redistribution structure includes at least one conductive layer, the semiconductor device is disposed on one side of the redistribution structure and is electrically connected to the conductive layer. The filling layer covers the periphery of the semiconductor device and has an accommodating portion. The shielding structure is disposed in the filling layer. The shielding structure includes a soldering material, and the soldering material is suitable for filling the accommodating portion to cover the semiconductor device.

According to some embodiments of the present disclosure, a semiconductor packaging structure includes a redistribution structure, a semiconductor device, a filling layer and a shielding structure. The redistribution structure includes at least a conductive layer, a ground pad and a conductive bump. The ground pad is disposed on a first side of the redistribution structure. The conductive bump is disposed on a second side of the redistribution structure. The first side is opposite to the second side. The semiconductor device is disposed on the first side of the redistribution structure and is electrically connected to the conductive layer. The filling layer covers the periphery of the semiconductor device and has an upper cover accommodating portion and an outer ring accommodating portion. The upper cover accommodating portion is located above the semiconductor device, and the outer ring accommodating portion is located correspondingly around the semiconductor device. The shielding structure is disposed in the filling layer. The shielding structure includes a soldering material. The soldering material is suitable for filling the upper cover accommodating portion and the outer ring accommodating portion to cover the semiconductor device.

According to some embodiments of the present disclosure, a method for manufacturing a semiconductor packaging structure is provided, which includes the following steps. A semiconductor device is disposed on a redistribution structure. The semiconductor device is disposed on one side of the redistribution structure and is electrically connected to a conductive layer of the redistribution structure. A filling layer is formed to cover the semiconductor device, and the filling layer is cured. A first portion of the filling layer is ablated with laser, and the first portion includes an outer ring accommodating portion penetrating the filling layer. A second portion of the filling layer is ablated with laser. The second portion includes an upper cover accommodating portion connected to the outer ring accommodating portion. The upper cover accommodating portion is located above the semiconductor device, and the outer ring accommodating portion is located around the semiconductor device. A soldering material is filled into the upper cover accommodating portion and the outer ring accommodating portion to form a shielding structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor packaging structure, comprising:
a redistribution structure comprising at least one conductive layer;
a semiconductor device disposed on one side of the redistribution structure and electrically connected to the conductive layer;
a filling layer covering a periphery of the semiconductor device and having an accommodating portion; and
a shielding structure provided in the filling layer, wherein the shielding structure contains a soldering material, and the soldering material is suitable for filling the accommodating portion to cover the semiconductor device.

2. The semiconductor packaging structure of claim 1, wherein the soldering material includes solder paste or lead-free solder.

3. The semiconductor packaging structure of claim 1, wherein the redistribution structure comprises at least one ground pad, and the ground pad is disposed on a first side of the redistribution structure.

4. The semiconductor packaging structure of claim 3, wherein the redistribution structure comprises at least one conductive bump, the conductive bump is disposed on a second side of the redistribution structure, and the first side is opposite to the second side.

5. The semiconductor packaging structure of claim 4, wherein the ground pad is electrically connected to the conductive bump.

6. The semiconductor packaging structure of claim 3, wherein the shielding structure is electrically connected to the ground pad.

7. The semiconductor packaging structure of claim 1, wherein the shielding structure comprises an upper cover correspondingly located above the semiconductor device.

8. The semiconductor packaging structure of claim 1, wherein the shielding structure comprises an outer ring sidewall, and the outer ring sidewall is correspondingly located around the semiconductor device.

9. The semiconductor packaging structure of claim 1, wherein a top surface of the shielding structure is coplanar with or slightly protrudes from a top surface of the filling layer.

10. A semiconductor packaging structure, comprising:
a redistribution structure comprising at least a conductive layer, a ground pad and a conductive bump, the ground pad being disposed on a first side of the redistribution structure, the conductive bump being disposed on a second side of the redistribution structure, and the first side being opposite to the second side;
a semiconductor device disposed on the first side of the redistribution structure and electrically connected to the conductive layer;
a filling layer covering a periphery of the semiconductor device and having an upper cover accommodating portion and an outer ring accommodating portion, the upper cover accommodating portion being correspondingly located above the semiconductor device, and the outer ring accommodating portion being correspondingly located around the semiconductor device; and
a shielding structure disposed in the filling layer, wherein the shielding structure comprises an upper cover correspondingly located above the semiconductor device and an outer ring sidewall correspondingly located around the semiconductor device.

11. The semiconductor packaging structure of claim 10, wherein the shielding structure is electrically connected to the ground pad.

12. The semiconductor packaging structure of claim 10, wherein the filling layer has an upper cover accommodating portion and an outer ring accommodating portion, the upper cover accommodating portion is correspondingly located above the semiconductor device, and the outer ring accommodating portion is correspondingly located around the semiconductor device.

13. The semiconductor packaging structure of claim 10, wherein the shielding structure contains a soldering material, and the soldering material is suitable for filling the upper cover accommodating portion and the outer ring accommodating portion to form the upper cover and the outer ring sidewall.

14. The semiconductor packaging structure of claim 10, wherein a top surface of the shielding structure is coplanar with or slightly protrudes from a top surface of the filling layer.

15. A method for manufacturing a semiconductor packaging structure, comprising:
disposing a semiconductor device on a redistribution structure, the semiconductor device being disposed on one side of the redistribution structure and being electrically connected to a conductive layer of the redistribution structure;
forming a filling layer to cover the semiconductor device, and curing the filling layer;
ablating a first portion of the filling layer by laser, the first portion comprising an outer ring accommodating portion penetrating the filling layer, the outer ring accommodating portion being correspondingly located around the semiconductor device;
ablating a second portion of the filling layer by laser, the second portion comprising an upper cover accommodating portion connected to the outer ring accommodating portion, and the upper cover accommodating portion being correspondingly located above the semiconductor device; and
filling a soldering material into the upper cover accommodating portion and the outer ring accommodating portion to form a shielding structure.

16. The method of claim 15, wherein after ablating the first portion of the filling layer, at least one ground pad is exposed at a bottom of the outer ring accommodating portion.

17. The method of claim 16, wherein the shielding structure is electrically connected to the ground pad.

18. The method of claim 15, wherein a depth of the upper cover accommodating portion is less than a depth of the outer ring accommodating portion.

19. The method of claim 15, wherein a top surface of the shielding structure is coplanar with or slightly protrudes from a top surface of the filling layer.

20. The method of claim 15, wherein ablating the first portion and the second portion of the filling layer comprising forming a spirally distributed ablation path from outside to inside, or first forming an outer ring ablation path on the filling layer to remove the first portion of the filling layer, and then forming a back-and-forth ablation path in a space surrounded by the outer ring ablation path to remove the second portion of the filling layer.
